(19) United States
(12) Patent Application Publication
(10) Pub. No.: US 2008/0185633 A1
(43) Pub. Date: Aug. 7, 2008

(54) Charge trap memory device with blocking insulating layer having higher-dielectric constant and larger energy band-gap and method of manufacturing the same

(75) Inventors: Sang-moo Choi, Yongin-si (KR); Hyo-sug Lee, Suwon-si (KR); Kwang-soo Seol, Suwon-si (KR); Sang-jin Park, Yongin-si (KR); Eun-ha Lee, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/068,060

(22) Filed: Feb. 1, 2008

(30) Foreign Application Priority Data
Feb. 2, 2007 (KR) 10-2007-0011269

(51) Int. Cl. H01L 29/788; H01L 29/792; H01L 21/336

(52) U.S. Cl. 257/321; 257/324; 438/287; 257/E21.423; 257/E29.3; 257/E29.309

(57) ABSTRACT

A charge trap memory device according to example embodiments may include a tunnel insulating layer provided on a substrate. A charge trap layer may be provided on the tunnel insulating layer. A blocking insulating layer may be provided on the charge trap layer, wherein the blocking insulating layer may include a lanthanide (e.g., lanthanum). The blocking insulating layer may further include aluminum and oxygen, wherein the ratio of lanthanide to aluminum may be greater than 1 (e.g., about 1.5 to about 2). The charge trap memory device may further include a buffer layer provided between the charge trap layer and the blocking insulating layer, and a gate electrode provided on the blocking insulating layer.

### PRIORITY STATEMENT

This application claims priority under 35 U.S.C. § 119 to Korean Patent Application No. 10-2007-0011269, filed on Feb. 2, 2007 in the Korean Intellectual Property Office (KIPO), the entire contents of which are incorporated herein by reference.

### BACKGROUND

1. Technical Field

Example embodiments relate to a charge trap memory device with a blocking insulating layer and a method of manufacturing the same.

2. Description of Related Art

A conventional SONOS memory device may include a first silicon oxide layer (SiO₂) formed as a tunnel insulating layer, wherein both ends of the first silicon oxide layer contact source and drain regions on a semiconductor substrate (e.g., channel region) between the source and drain regions. The first silicon oxide layer may tunnel charges. A silicon nitride layer (Si₃N₄) may be formed on the first silicon oxide layer as a charge trap layer. The silicon nitride layer may store data and trap charges which have passed through the first silicon oxide layer. A second silicon oxide layer may be formed on the silicon nitride layer to block charges that pass upwards through the silicon nitride layer. A gate electrode may be formed on the second silicon oxide layer.

Consequently, in a conventional SONOS memory device, the permittivity of the silicon nitride layer and the silicon oxide layer may be relatively low, and the density of the trap site in the silicon nitride layer may be relatively low, thus resulting in a higher operation voltage. Additionally, the data recording speed (e.g., programming speed) and the charge retention time in vertical and horizontal directions may be relatively low.

However, when an aluminum oxide (Al₂O₃) layer having a higher dielectric constant than silicon oxide is used as the blocking insulating layer instead of the second silicon oxide layer, programming speed and retention characteristics may be improved. Aluminum oxide may have a dielectric constant approximately double to that of silicon oxide and, thus, may be advantageous for increasing programming speed. For example, silicon oxide (SiO₂) may have a dielectric constant of about 3.9, while aluminum oxide (Al₂O₃) may have a dielectric constant of about 9. Thus, a higher voltage may be applied to the tunnel insulating layer to increase programming speed because of the higher dielectric constant of the blocking insulating layer. Conversely, the silicon oxide layer may have a lower dielectric constant and, thus, may be less beneficial for increasing programming speed.

Forming the blocking insulating layer of a higher-k dielectric material may also be advantageous with regard to erasing characteristics, because the physical thickness of the blocking insulating layer may be increased. Thus, the voltage applied to the blocking insulating layer may be lowered, while the voltage applied to the tunneling insulating layer may be increased during an erasing operation. When the voltage applied to the blocking insulating layer is lowered, electrons shifting from the gate electrode may be reduced. Also, when the voltage applied to the tunneling insulating layer is increased, holes may shift to the substrate, thereby improving erasing characteristics.

However, when the dielectric constant of a material is increased, the energy band-gap may decrease. Consequently, a smaller energy band-gap may be disadvantageous to erasing characteristics, because electrons may shift from the gate electrode to the charge trap layer as a result of a negative bias voltage which may be applied during the erasing operation.

### SUMMARY

A charge trap memory device according to example embodiments may include a tunnel insulating layer provided on a substrate. A charge trap layer may be provided on the tunnel insulating layer. A blocking insulating layer may be provided on the charge trap layer, wherein the blocking insulating layer may include a lanthanide (Ln). Accordingly, example embodiments provide a charge trap memory device with a blocking insulating layer having a higher dielectric constant and a larger energy band-gap.

The blocking insulating layer may also include a lanthanide (Ln) and aluminum (Al). Additionally, the amount of lanthanide may be higher than that of aluminum. For example, the composition ratio of lanthanide to aluminum may range from about 1.5 to about 2. The blocking insulating layer may further include a lanthanide (Ln), aluminum (Al), and oxygen (O). Additionally, the lanthanide may be lanthanum (La). For example, the blocking insulating layer may include lanthanum (La), aluminum (Al), and oxygen (O). The composition ratio of lanthanum to aluminum may range from about 1.5 to about 2.

The charge trap memory device may further include a buffer layer provided between the charge trap layer and the blocking insulating layer. The buffer layer may reduce or prevent an interfacial reaction between the charge trap layer and the blocking insulating layer. The buffer layer may be formed of a higher-k dielectric material, a transition metal nitride, or an oxide thereof. For example, the buffer layer may be formed of AlO, HfO, ZrO, TiO, TaO, ScO, GdO, LuO, SmO, TiN, AlN, or an oxide thereof. The charge trap layer may be formed of polysilicon, nitride, nanodots, or a higher-k dielectric material. The charge trap memory device may further include a gate electrode provided on the blocking insulating layer.

A method of manufacturing a charge trap memory device according to example embodiments may include forming a tunnel insulating layer on a substrate. A charge trap layer may be formed on the tunnel insulating layer, and a blocking insulating layer may be formed on the charge trap layer, wherein the blocking insulating layer may include a lanthanide.

### BRIEF DESCRIPTION OF THE DRAWINGS

FIG. 1 is a schematic cross-sectional view of a charge trap memory device according to example embodiments;

FIG. 2 is a graph illustrating a result of auger electron spectroscopy (AES) with respect to a LaAlO thin film having a La/Al composition ratio of about 0.5;

FIG. 3 is a graph illustrating a result of AES with respect to a LaAlO thin film having a La/Al composition ratio of about 1;

FIG. 4 is a graph illustrating a result of AES with respect to a LaAlO thin film having a La/Al composition ratio of about 2;

FIG. 5 is a graph illustrating an energy band-gap of a LaAlO thin film measured using a REELS analysis method with respect to a composition ratio of La/Al;

FIG. 6A is a graph illustrating a result of REELS analysis performed with respect to a LaAlO thin film having a La/Al composition ratio of about 1;

FIG. 6B is a graph illustrating a result of REELS analysis performed with respect to a LaAlO thin film having a La/Al composition ratio of about 2;

FIG. 7 is a schematic cross-sectional view of another charge trap memory device according to example embodiments;

FIGS. 8A and 8B are transmission electron microscopy (TEM) images of a LaAlO (LAO) dielectric insulating layer deposited as a blocking insulating layer on a SiN charge trap layer;

FIGS. 9A and 9B are graphs illustrating results of AES analysis performed with respect to a LaAlO dielectric insulating layer when a buffer layer is formed between a SiN charge trap layer and a LaAlO dielectric insulating layer having La/Al ratios of about 1 and about 2, respectively;

FIGS. 10A and 10B are graphs comparing programming and erasing characteristics of charge trap memory devices according to example embodiments using a LaAlO thin film having a La/Al ratio of about 2 as a blocking insulating layer with those of a charge trap memory device (comparison example) using an aluminum oxide (AlO) layer as a blocking insulating layer;

FIGS. 11A and 11B are TEM images of samples according to example embodiments having La/Al ratios of about 1 and about 2, respectively;

FIG. 12A is a graph illustrating a relationship between a gate voltage V_{g} and a capacitance of the sample according to example embodiments of FIG. 11A; and

FIG. 12B is a graph illustrating a relationship between a gate voltage V_{g} and a capacitance of the sample according to example embodiments of FIG. 11B.

### DETAILED DESCRIPTION OF EXAMPLE EMBODIMENTS

Example embodiments will be described in detail with reference to the accompanying drawings. In the drawings, the thicknesses of layers and regions may have been exaggerated for clarity.

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

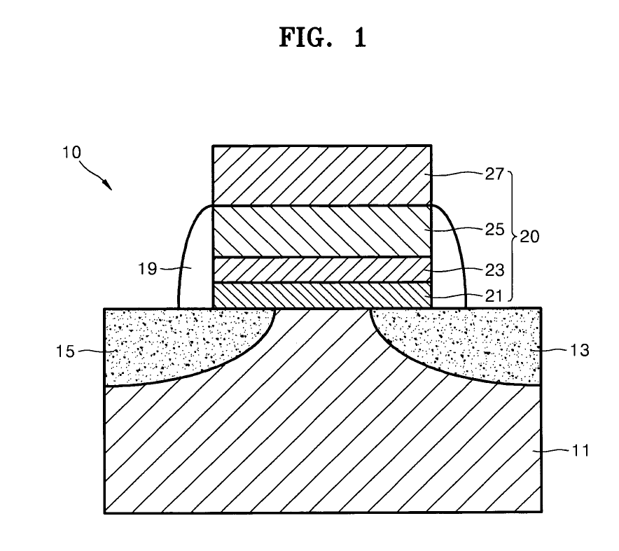

FIG. 1 is a schematic cross-sectional view of a charge trap memory device 10 according to example embodiments. Referring to FIG. 1, the charge trap memory device 10 may include a substrate 11 and a gate structure 20 formed on the substrate 11. The substrate 11 may be doped with a conductive impurity to form first and second impurity areas 13 and 15 in the substrate 11. One of the first and second impurity areas 13 and 15 may be used as a drain (D), while the other may be used as a source (S). The gate structure 20 may include a tunnel insulating layer 21 formed on the substrate 11, a charge trap layer 23 formed on the tunnel insulating layer 21, and/or a blocking insulating layer 25 formed on the charge trap layer 23. A gate electrode 27 may be formed on the blocking insulating layer 25. A spacer 19 may also be formed on a sidewall of the gate structure 20.

The tunnel insulating layer 21 may tunnel charges and may be formed on the substrate 11 so as to contact the first and second impurity areas 13 and 15. The tunnel insulating layer 21 may be a tunneling oxide layer. For example, the tunnel insulating layer 21 may be formed of SiO₂, higher dielectric (higher-k) oxides, or a combination thereof. Alternatively, the tunnel insulating layer 21 may be formed of silicon nitride (Si₃N₄). The silicon nitride may have a lower impurity density (e.g., an impurity density comparable with that of silicon oxide) and beneficial interfacial characteristics with silicon. To form higher-quality silicon nitride, the silicon nitride for the tunnel insulating layer 21 may be formed using a suitable manufacturing method (e.g., jet vapor deposition). Alternatively, the tunnel insulating layer 21 may be a dual layer formed of silicon nitride and oxide. Thus, the tunnel insulating layer 21 may be a single layer formed of oxide or nitride or may be a plurality of layers having different energy band-gaps.

The charge trap layer 23 may trap charges so as to store information. The charge trap layer 23 may be formed of polysilicon, nitride, a higher-k dielectric, or nanodots. For example, the charge trap layer 23 may be formed of Si₃N₄, SiO₂, HfO₂, ZrO₂, Al₂O₃, HfSiON, HfON, or HfAlO. The charge trap layer 23 may include a plurality of nanodots disposed intermittently as charge trap sites. For example, the nanodots may be nanocrystals. The gate electrode 27 may be formed of a metal layer. For example, the gate electrode 27 may be formed of aluminum (Al), ruthenium (Ru), TaN, or a silicide material (e.g., NiSi).

The blocking insulating layer 25 may block charges from shifting upwards through the charge trap layer 23. The blocking insulating layer 25 may be formed of a material including a lanthanide (Ln) so as to have a higher dielectric constant and a larger energy band-gap. Ln may refer to the 15 elements ranging from lanthanum (La) as the 57^{th} element to lutetium (Lu) as the 71^{st} element. Accordingly, Ln may be regarded as including at least one of the 15 elements.

The blocking insulating layer 25 may also be formed of a material including a lanthanide (Ln) and aluminum (Al). The amount of Ln may be higher than the amount of Al. For example, the composition ratio of Ln to Al may be greater than about 1 (e.g., between about 1.5 and about 2 or higher). The blocking insulating layer 25 may be additionally formed of a higher-k dielectric insulating material including a lanthanide (Ln), aluminum (Al), and oxygen (O). The lanthanide (Ln) may be lanthanum (La). For example, the blocking insulating layer 25 may be formed of LaAlO or LaAlON. The composition ratio of La to Al may be greater than about 1 (e.g., between about 1.5 and about 2 or higher). For example, the blocking insulating layer 25 may be formed of La₄Al₂O₉ having a La/Al composition ratio of 2.

LaAlO may have a relatively large energy band-gap and a higher dielectric constant than Al₂O₃. For example, Al₂O₃ may have an energy band-gap of about 6.1-6.2 eV and a dielectric constant of about 9. LaAlO₃ with a La/Al composition ratio of 1 may have an energy band-gap of about 5.65 eV and a dielectric constant of about 12, and La₄Al₂O₉ with a La/Al composition ratio of 2 may have an energy band-gap of about 5.95 eV and a dielectric constant of about 20. Thus, while LaAlO₃ and La₄Al₂O₉ may have a similar energy band-gap to aluminum oxide, LaAlO₃ and La₄Al₂O₉ may have a higher dielectric constant.

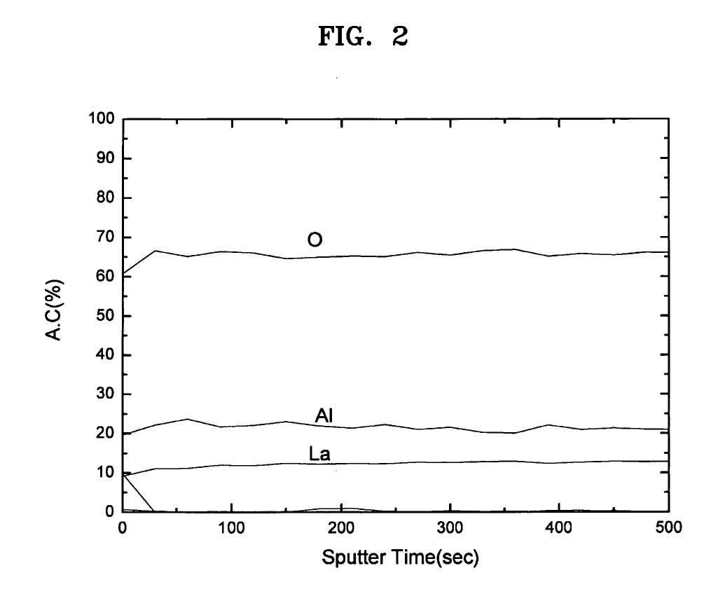

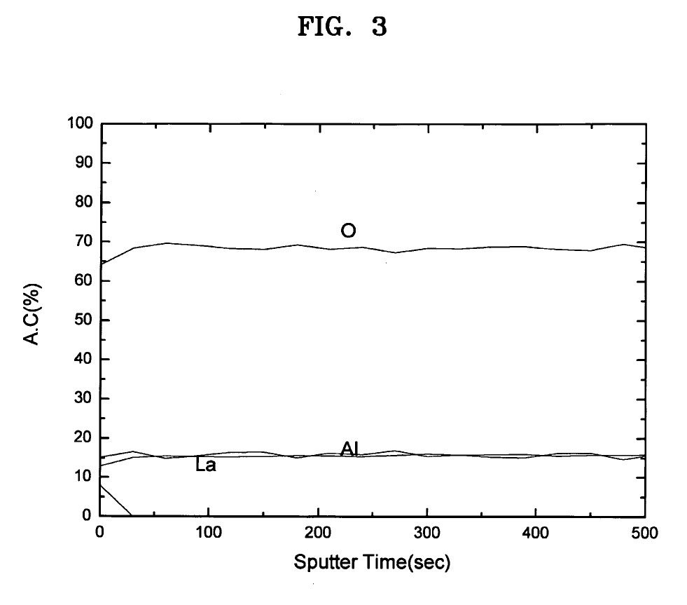

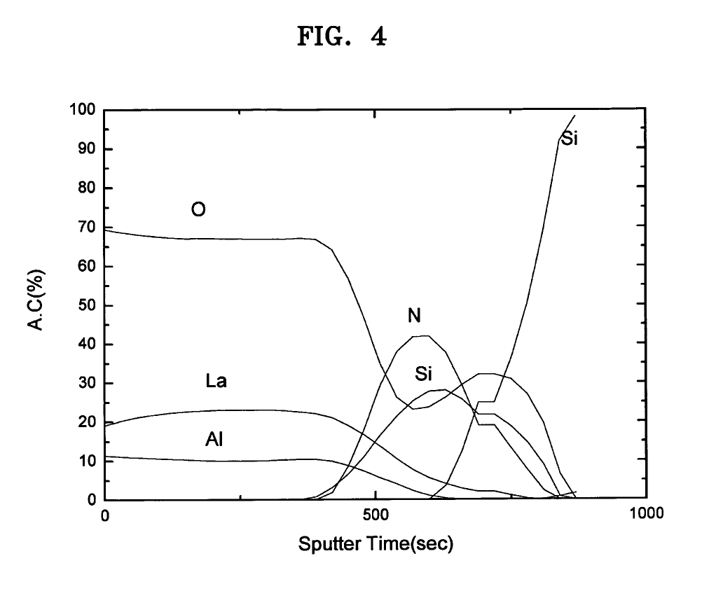

FIG. 2 is a graph illustrating a result of an auger electron spectroscopy (AES) with respect to a LaAlO thin film having a La/Al composition ratio of about 0.5. FIG. 3 is a graph illustrating a result of an AES with respect to a LaAlO thin film having a La/Al composition ratio of about 1. FIG. 4 is a graph illustrating a result of an AES with respect to a LaAlO thin film having a La/Al composition ratio of about 2. The results of the AES's shown in FIGS. 2 through 4 illustrate that a thin film having a La/Al composition ratio of about 0.5, 1, or 2 may be manufactured.

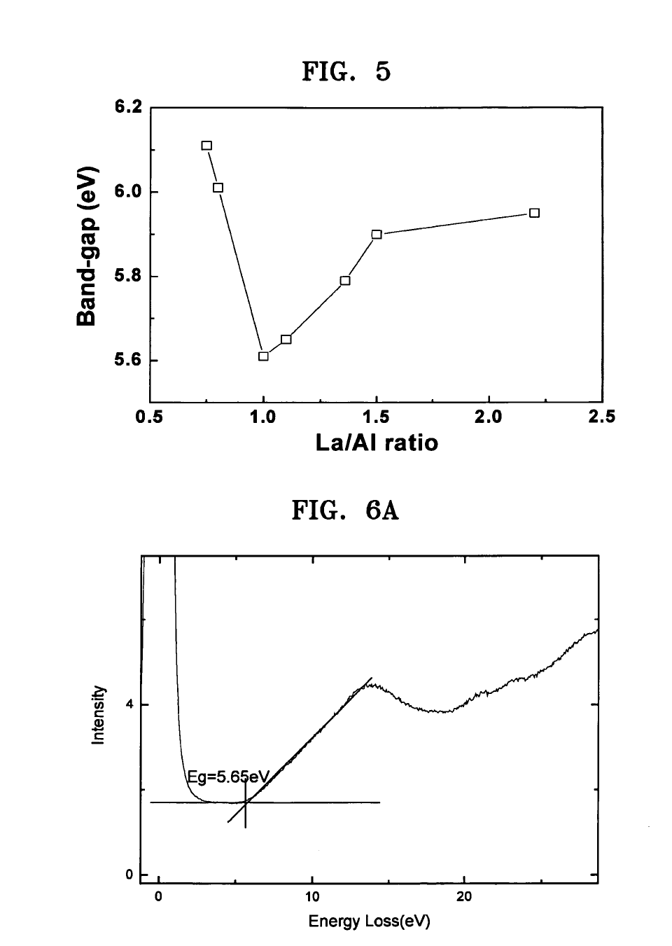

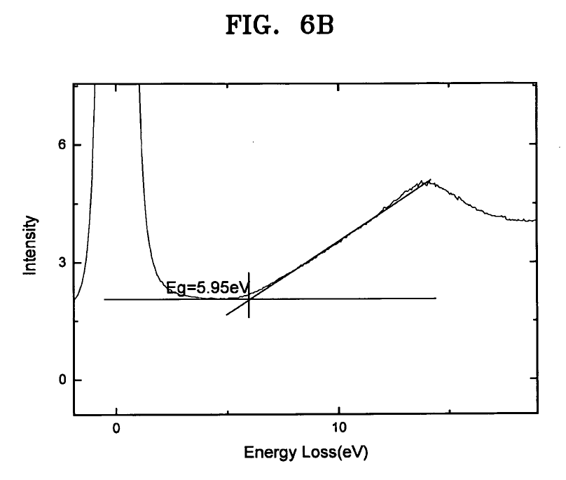

FIG. 5 is a graph obtained using a REELS analysis method illustrating an energy band-gap of a LaAlO thin film with respect to La/Al composition ratio. The results of the REELS analysis of the energy band-gaps of LaAlO thin films having La/Al composition ratios of about 1 and about 2 are illustrated in FIGS. 6A and 6B, respectively. FIG. 6A is a graph illustrating the result of a REELS analysis with respect to a LaAlO thin film having a La/Al composition ratio of about 1. FIG. 6B is a graph illustrating the result of a REELS analysis with respect to a LaAlO thin film having a La/Al composition ratio of about 2. Referring to FIGS. 5 through 6B, an energy band-gap E_{g} of a LaAlO thin film having a La/Al composition ratio of about 1 is about 5.65 eV, and an energy band-gap E_{g} of a LaAlO thin film having a La/Al composition ratio of about 2 is about 5.95 eV. Thus, increasing the La/Al composition ratio of LaAlO to a ratio greater than 1 may increase the dielectric constant and the energy band-gap.

A charge trap memory device 10 having a blocking insulating layer 25 formed of a higher-k insulating material including a lanthanide (e.g., Ln in combination with Al and/or O) may have improved characteristics. Memory characteristics (e.g., programming and erasing characteristics) and reliability, which may have been lowered by a reduction of operation voltage, may be improved, because a higher-k insulating layer formed of Ln, Al, and O may have a higher dielectric constant and a larger energy band-gap depending on the Ln/Al composition ratio. The blocking insulating layer 25 may be formed of a material having a higher dielectric constant than aluminum oxide. Thus, the voltage applied to the blocking insulating layer 25, as well as the voltage for the overall operation, may be lowered. As a result, the operation voltage for programming and erasing operations may be lowered.

The voltage applied to the tunnel insulating layer 21 may also be maintained without increasing the operating voltage. When programming and erasing characteristics are to be maintained, the thickness of the tunnel insulating layer 21 may be increased so as to improve reliability of the charge trap memory device. Consequently, a charge leakage occurring at a relatively high temperature after several write and erase operations may be reduced. Accordingly, when the blocking insulating layer 25 is formed of a material including lanthanide (e.g., Ln in combination with Al and/or O) so as to have a higher dielectric constant and a larger band-gap, a charge trap memory device 10 having beneficial programming speed and erasing characteristics may be realized.

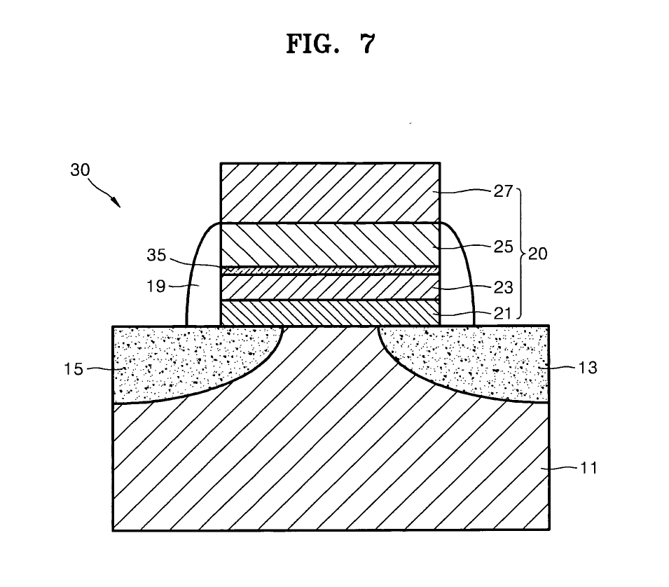

FIG. 7 is a schematic cross-sectional view of another charge trap memory device 30 according to example embodiments. Referring to FIG. 7, the charge trap memory device 30 may be substantially the same as the charge trap memory device 10 of FIG. 1, except that a buffer layer 35 may be formed between the charge trap layer 23 and the blocking insulating layer 25 to reduce or prevent an interface reaction between the charge trap layer 23 and the blocking insulating layer 25. In the drawings, like reference numerals may denote like elements. Thus, the previous description of like elements will not be repeated.

The buffer layer 35 may be formed of various materials in a thin film. The buffer layer 35 may be formed of a higher-k insulating material, a transition metal nitride, an oxide of a higher-k insulating material, or an oxide of a transition metal nitride. For example, a higher-k insulating material may include AlO, HfO, ZrO, TiO, TaO, ScO, GdO, LuO, or SmO. A transition metal nitride may include TiN or AlN. When the buffer layer 35 is formed between the charge trap layer 23 and the blocking insulating layer 25 as shown in FIG. 7, the charge trap memory device 30 may have a clearer interface between the charge trap layer 23 and the blocking insulating layer 25.

When the blocking insulating layer 25 is formed of a material including a lanthanide (e.g., a higher-k insulating material including Ln, Al, and O), the blocking insulating layer 25 may interact with the charge trap layer 23 because of the relative reactivity of the lanthanide. Consequently, an interfacial reaction may decrease the operation characteristics of a memory device. However, the charge trap memory device 30 according to example embodiments may reduce or prevent the occurrence of an interfacial reaction so as to reduce or prevent the deterioration of operation characteristics. Thus, the charge trap memory device 30 may have further improved operation characteristics.

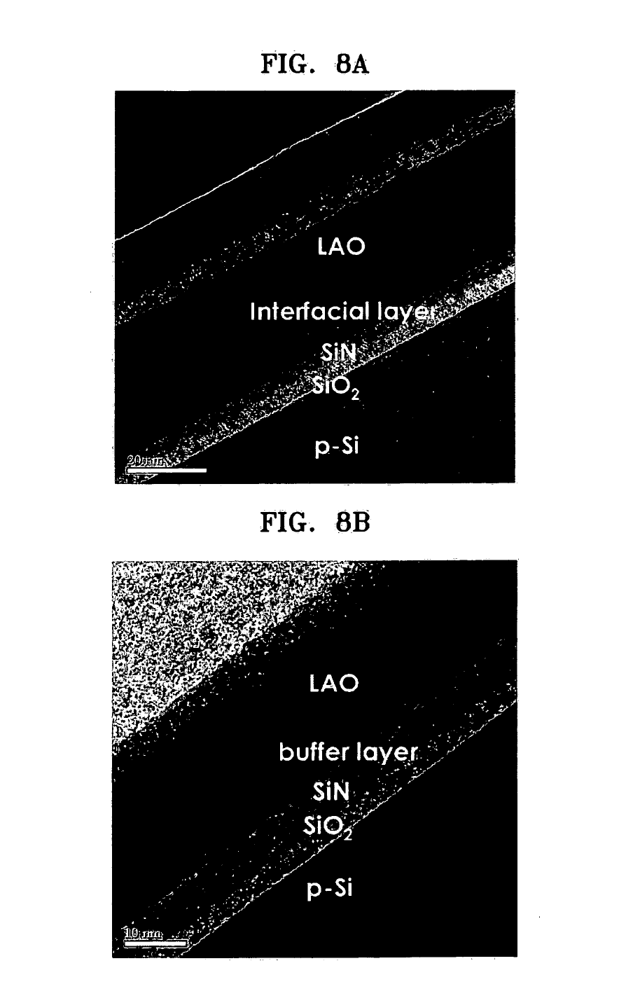

FIGS. 8A and 8B are transmission electron microscopy (TEM) images of a LaAlO (LAO) blocking insulating layer formed on a SiN charge trap layer. FIG. 8A illustrates a sample according to example embodiments that does not include a buffer layer (e.g., the charge trap memory device 10 of FIG. 1). FIG. 8B illustrates a sample according to example embodiments that does include a buffer layer (e.g., the charge trap memory device 30 of FIG. 7). Referring to FIGS. 8A and 8B, the samples may be thermally-treated at a temperature of about 800° C. for about 2 minutes. The thermal treatment may be representative of a process that may be utilized to form doping areas used as a source and a drain. Thus, the thermal stability of a memory device may be relatively important.

Referring to FIG. 8A, an interfacial reaction may occur when a higher-k insulating layer, formed of La, Al, and O (LAO), is used as a blocking insulating layer. Consequently, an interfacial layer may be observed between the SiN charge trap layer and the LaAlO blocking insulating layer. However, referring to FIG. 8B, if a buffer layer is provided between the SiN charge trap layer and the LaAlO blocking insulating layer, the formation of the interfacial layer may be reduced or prevented. Thus, when a buffer layer is formed between the charge trap layer and the blocking insulating layer as shown in FIG. 8B, an interfacial reaction may be reduced or prevented so as to further improve the operation characteristics of the memory device.

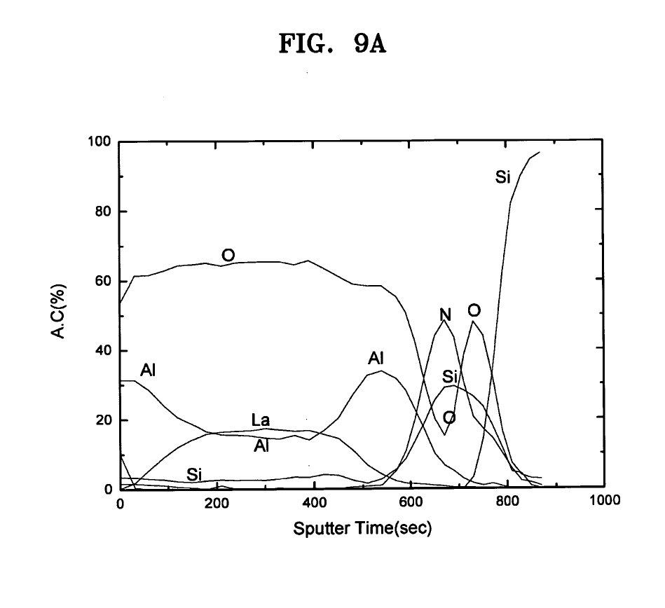

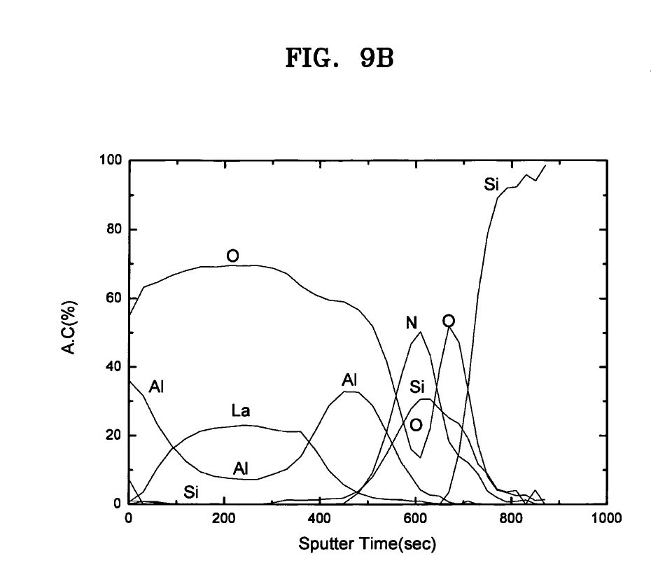

FIGS. 9A and 9B are graphs illustrating the results of AES analyses of a LaAlO higher-k insulating layer when a buffer layer is formed between a SiN charge trap layer and a LaAlO higher-k insulating layer having a La/Al ratio of about 1 and about 2, respectively. As illustrated by FIGS. 9A and 9B, the higher-k insulating layer may be formed of a combination of La, Al, and O having a La/Al composition ratio about 1 or about 2, respectively. The La/Al composition ratio may be adjusted to the desired ratio (e.g., greater than 2).

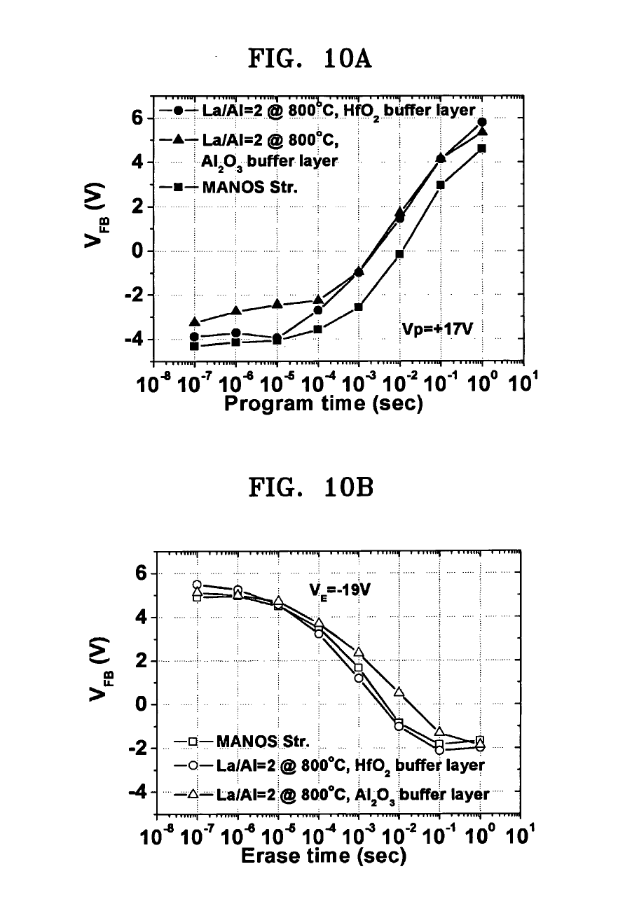

FIGS. 10A and 10B illustrate programming and erasing characteristics of a charge trap memory device according to example embodiments. Sample 1, sample 2, and a comparison sample were used to obtain the results of FIGS. 10A and 10B. Regarding sample 1, a blocking insulating layer was formed of a La₄Al₂O₉ higher-k insulating layer having a La/Al composition ratio of 2, and a buffer layer was formed of Al₂O₃. Sample 1 was thermally-treated at a temperature of about 800° C. Regarding sample 2, a blocking insulating layer was formed of a La₄Al₂O₉ higher-k insulating layer having a La/Al composition ratio of 2, and a buffer layer was formed of HfO₂. Sample 2 was thermally-treated at a temperature of about 800° C. In FIGS. 10A and 10B, “MANOS Str.” may denote a comparison sample having a Al₂O₃/SiN/SiO₂/Si structure. The horizontal axis of FIG. 10A may denote programming time, and the horizontal axis of FIG. 10B may denote erasing time. The vertical axes of FIGS. 10A and 10B may denote flat-band voltages VFB.

Referring to FIG. 10A, the programming time may be faster when a LaAlO higher-k insulating layer is used as a blocking insulating layer compared to when an aluminum oxide layer is used as a blocking insulating layer. A voltage applied to a La₄Al₂O₉ blocking insulating layer may decrease, while a voltage applied to a tunnel insulating layer may increase because of the higher dielectric constant of La₄Al₂O₉. Consequently, a larger number of electrons may shift from the substrate so as to be trapped in a trap site of the charge trap layer. Also, a faster programming time may be observed when a La₄Al₂O₉ higher-k insulating layer is used as a blocking insulating layer regardless of the type of buffer layer used. Thus, faster programming time may be obtained when a buffer layer is formed between the charge trap layer and the blocking insulating layer having a lanthanide.

Referring to FIG. 10B, the erasing time obtained with the LaAlO blocking insulating layer (in samples 1 and 2) may be similar to that obtained with the Al₂O₃ blocking insulating layer (in the comparison sample). When a buffer layer is formed between the charge trap layer and the blocking insulating layer, a charge trap memory device having improved programming speed, favorable erasing characteristics, and a clear interface between the charge trap layer and the blocking insulating layer may be realized.

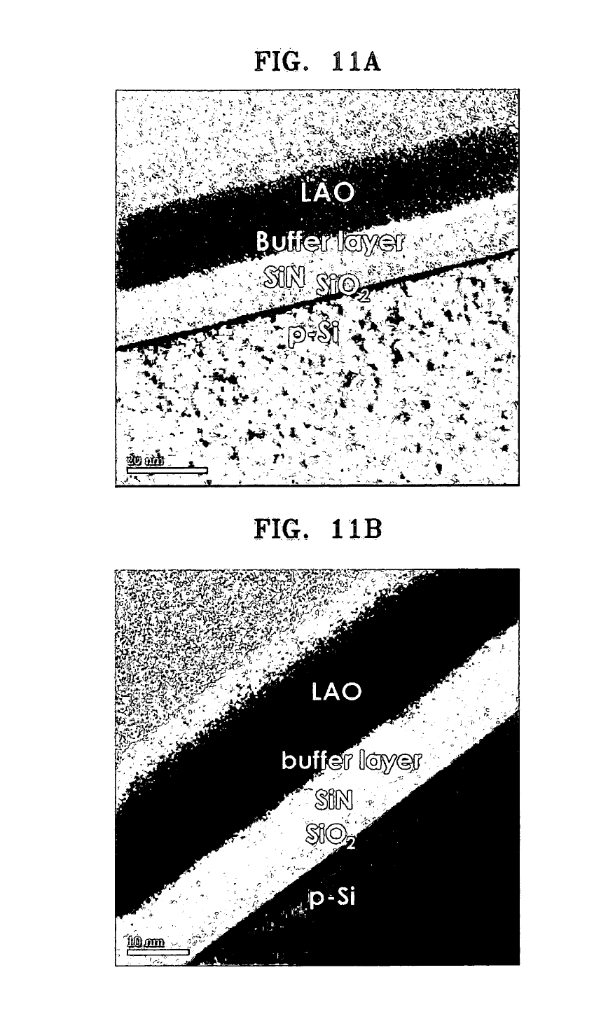

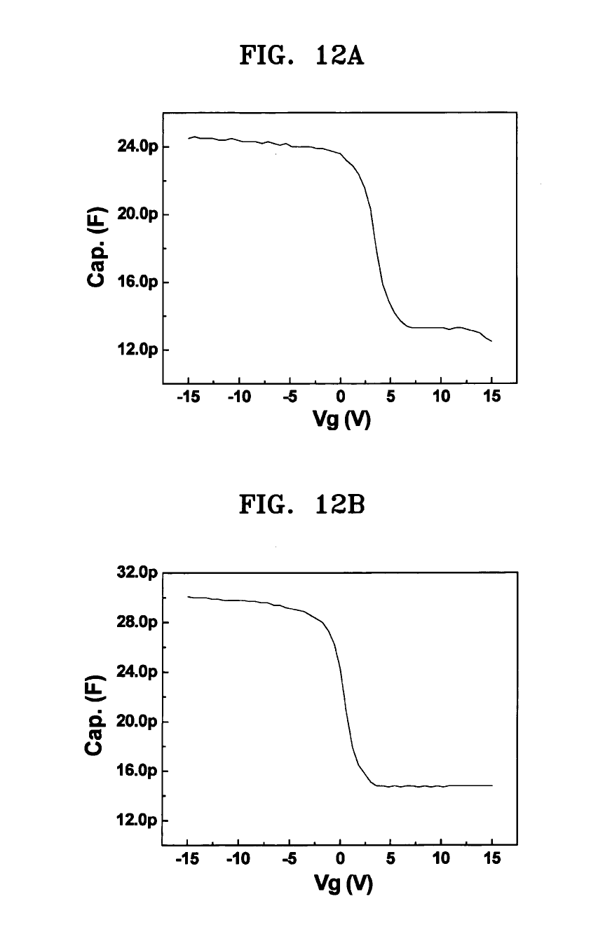

FIGS. 11A and 11B are TEM images of samples according to example embodiments having La/Al composition ratios of about 1 and about 2, respectively. The TEM image of FIG. 11B may be substantially the same as that of FIG. 8B. FIG. 12A is a graph illustrating the relationship between gate voltage V_{g} and the capacitance of the sample of FIG. 11A. FIG. 12B is a graph illustrating the relationship between gate voltage V_{g} and the capacitance of the sample of FIG. 11B. The physical thickness of the LAO in FIG. 11A is about 22.1 nm, and the accumulated capacitance in the graph of FIG. 12A is about 25 pF/10⁴ μm². When the La/Al composition ratio is about 1, the dielectric constant of the blocking insulating layer including the buffer layer is about 12. The physical thickness of the LAO in FIG. 11B is about 25.3 nm, and the accumulated capacitance in the graph of FIG. 12B is about 30 pF/10⁴ μm². When the La/Al composition ratio is about 2, the dielectric constant of the blocking insulating layer including the buffer layer is about 20.

As described above, a blocking insulating layer of a charge trap memory device according to example embodiments may be formed of a material including a lanthanide (e.g., lanthanum). Thus, a higher dielectric constant and a larger band-gap may be achieved so as to realize a charge trap memory device having beneficial programming and erasing characteristics.

While example embodiments have been disclosed herein, it should be understood that other variations may be possible. Such variations are not to be regarded as a departure from the spirit and scope of example embodiments of the present disclosure, and all such modifications as would be obvious to one skilled in the art are intended to be included within the scope of the following claims.

What is claimed is:

1. A charge trap memory device comprising:
a tunnel insulating layer on a substrate;
a charge trap layer on the tunnel insulating layer; and
a blocking insulating layer on the charge trap layer, wherein the blocking insulating layer includes a lanthanide.

2. The charge trap memory device of claim 1, wherein the blocking insulating layer further includes aluminum.

3. The charge trap memory device of claim 2, wherein the blocking insulating layer has a larger amount of lanthanide than aluminum.

4. The charge trap memory device of claim 3, wherein a ratio of lanthanide to aluminum ranges from about 1.5 to about 2.

5. The charge trap memory device of claim 2, wherein the blocking insulating layer further includes oxygen.

6. The charge trap memory device of claim 5, wherein the blocking insulating layer includes one of LaAlO and LaAlON.

7. The charge trap memory device of claim 2, wherein the lanthanide is lanthanum.

8. The charge trap memory device of claim 7, wherein a ratio of lanthanum to aluminum ranges from about 1.5 to about 2.

9. The charge trap memory device of claim 1, further comprising:
a gate electrode on the blocking insulating layer.

10. The charge trap memory device of claim 1, further comprising:
a buffer layer between the charge trap layer and the blocking insulating layer.

11. The charge trap memory device of claim 10, wherein the buffer layer is formed of one of a higher-k dielectric material, a transition metal nitride, and an oxide thereof.

12. The charge trap memory device of claim 11, wherein the buffer layer is formed of one of AlO, HfO, ZrO, TiO, TaO, ScO, GdO, LuO, SmO, TiN, AlN, and an oxide thereof.

13. The charge trap memory device of claim 1, wherein the charge trap layer is formed of one of polysilicon, nitride, nanodots, and a higher-k dielectric material.

14. The charge trap memory device of claim 10, further comprising:
a gate electrode on the blocking insulating layer.

15. A method of manufacturing a charge trap memory device, comprising:
forming a tunnel insulating layer on a substrate;
forming a charge trap layer on the tunnel insulating layer; and
forming a blocking insulating layer on the charge trap layer, wherein the blocking insulating layer includes a lanthanide.

16. The method of claim 15, wherein the blocking insulating layer further includes aluminum.

17. The method of claim 16, wherein the blocking insulating layer has a larger amount of lanthanide than aluminum.

18. The method of claim 16, wherein the blocking insulating layer further includes oxygen.

19. The method of claim 15, further comprising:
forming a buffer layer between the charge trap layer and the blocking insulating layer.

20. The method of claim 15, further comprising:
forming a gate electrode on the blocking insulating layer.
